(19) United States
(12) Patent Application Publication
(10) Pub. No.: US 2015/0234268 A1
(43) Pub. Date: Aug. 20, 2015

(54) MASK PATTERN CORRECTION METHOD AND NON-TRANSITORY COMPUTER-READABLE RECORDING MEDIUM CONTAINING A MASK PATTERN CORRECTION PROGRAM

(71) Applicant: Kabushiki Kaisha Toshiba, Minato-ku (JP)

(72) Inventors: Shinichi NAKAGAWA, Yokohama-shi (JP); Kazunori IIDA, Yokkaichi-shi (JP); Masanari KAJIWARA, Yokohama-shi (JP); Motohiro OKADA, Yokohama-shi (JP)

(73) Assignee: Kabushiki Kaisha Toshiba, Minato-ku (JP)

(21) Appl. No.: 14/323,484

(22) Filed: Jul. 3, 2014

(30) Foreign Application Priority Data
Feb. 18, 2014 (JP) 2014-028643

(51) Int. Cl. G03F 1/42; G01B 21/22

(52) U.S. Cl. CPC G03F 1/42; G01B 21/22

(57) ABSTRACT

According to one embodiment, a first auxiliary pattern is arranged at a corner of a mask pattern, an arrangement position of a second auxiliary pattern is calculated based on an opening angle of a resist pattern to which the mask pattern is transferred, and the second auxiliary pattern is arranged at the arrangement position.

### CROSS-REFERENCE TO RELATED APPLICATIONS

This application is based upon and claims the benefit of priority from Japanese Patent Application No. 2014-28643, filed on Feb. 18, 2014; the entire contents of which are incorporated herein by reference.

### FIELD

Embodiments described herein relate generally to a mask pattern correction method and non-transitory computer-readable recording medium containing a mask pattern correction program.

### BACKGROUND

As circuit patterns become finer, resist patterns decrease in resolution. There is a method of compensating for reduction in resolution of resist patterns by which auxiliary patterns are arranged on a mask pattern.

### BRIEF DESCRIPTION OF THE DRAWINGS

FIG. 1A is a schematic block diagram of a mask pattern correction device and peripheral devices thereof according to a first embodiment, FIG. 1B is a schematic cross-sectional view of an exposure device in which the mask pattern correction device illustrated in FIG. 1A is used, FIG. 1C is a cross-sectional view illustrating a process after formation of resist patterns, and FIG. 1D is a cross-sectional view illustrating a process after formation of processed patterns;

FIG. 2A is a plane view of one example of designed patterns for use in a mask pattern correction method according to the first embodiment, FIG. 2B is a plane view illustrating a method of compensating for process conversion differences in the designed patterns illustrated in FIG. 2A, FIG. 2C is a plane view of a configuration in which first auxiliary patterns are arranged on the designed patterns illustrated in FIG. 2B, and FIG. 2D is a plane view of a configuration in which second auxiliary patterns are arranged on the designed patterns illustrated in FIG. 2C;

FIGS. 3A and 3B are plane views illustrating a method of arranging the first auxiliary patterns and the second auxiliary patterns;

FIG. 4 is a cross-sectional view illustrating a method of calculating an opening angle in an opening angle model;

FIG. 5 is a flow chart of the mask pattern correction method according to the first embodiment;

FIG. 6A is a plane view illustrating a result of simulation of a resist pattern without the first auxiliary patterns and the second auxiliary patterns, and FIG. 6B is an enlarged plane view of a corner of the resist pattern illustrated in FIG. 6A;

FIG. 7A is a plane view of a result of simulation of a resist pattern with the first auxiliary patterns and the second auxiliary patterns, and FIG. 7B is an enlarged plane view of a corner of the resist pattern illustrated in FIG. 7A; and

FIG. 8 is a block diagram of a hardware configuration of a pattern generation device according to a second embodiment.

### DETAILED DESCRIPTION

According to one embodiment, a first auxiliary pattern is arranged at a corner of a mask pattern, an arrangement position of a second auxiliary pattern is calculated based on an opening angle of a resist pattern to which the mask pattern is transferred, and the second auxiliary pattern is arranged at the arrangement position.

Exemplary embodiments of a mask pattern correction method will be explained below in detail with reference to the accompanying drawings. The present invention is not limited to the following embodiments.

### First Embodiment

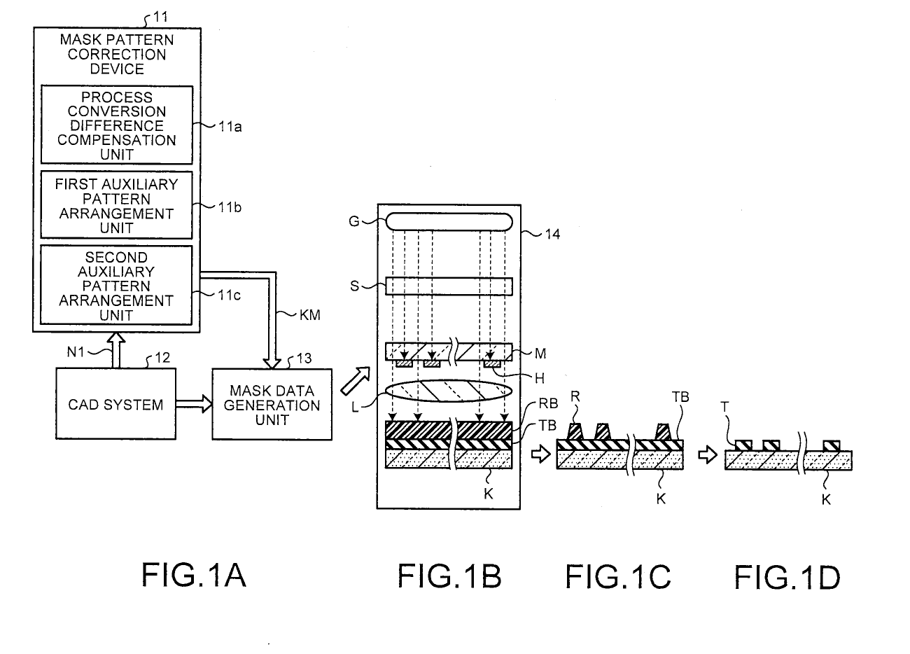

FIG. 1A is a schematic block diagram of a mask pattern correction device and peripheral devices thereof according to a first embodiment, FIG. 1B is a schematic cross-sectional view of an exposure device in which the mask pattern correction device illustrated in FIG. 1A is used, FIG. 1C is a cross-sectional view illustrating a process after formation of resist patterns, and FIG. 1D is a cross-sectional view illustrating a process after formation of processed patterns.

Referring to FIG. 1A, a mask pattern correction device 11 is provided with a process conversion difference compensation unit 11a, a first auxiliary pattern arrangement unit 11b, and a second auxiliary pattern arrangement unit 11c. A CAD system 12 and a mask data generation unit 13 are provided as peripheral devices of the mask pattern correction device 11. In addition, referring to FIG. 1B, an exposure device 14 is provided with a light source G, a diaphragm S, a photomask M, and a lens L.

The process conversion difference compensation unit 11a corrects a mask pattern H according to a process conversion difference between a resist pattern R to which the mask pattern H is transferred and a processed pattern T. The process conversion difference can be calculated based on a difference between an actual measurement value of a dimension of the resist pattern R and an actual measurement value of a dimension of the processed pattern T. To increase the accuracy of calculating the process conversion difference, the process conversion difference may be calculated based on an opening angle of the resist pattern. The first auxiliary pattern arrangement unit lib arranges first auxiliary patterns at corners of the mask pattern H. The second auxiliary pattern arrangement unit 11c calculates arrangement positions of second auxiliary patterns based on the opening angle of the resist pattern R, and arranges the second auxiliary patterns at that arrangement positions. The second auxiliary patterns can be arranged adjacent to the corners of the mask pattern H.

The mask pattern H can use rectangular patterns that are repeatedly aligned at a predetermined pitch. For example, the mask pattern H can correspond to a pattern for an active area or gate of a sense amplifier in an NAND memory or the like. The opening angle of the resist pattern R can represent to what degree the opening portion of the resist pattern R is open with respect to film thickness of the resist pattern R. The first auxiliary patterns and the second auxiliary patterns can reduce rounding of the corners of the resist pattern R to which the mask pattern H is transferred.

In addition, at the CAD system 12, designed layout data N1 on a semiconductor integrated circuit is generated and transmitted to the mask pattern correction device 11 and the mask data generation unit 13. Then, at the process conversion difference compensation unit 11a, the mask pattern H is corrected according to a process conversion difference between the resist pattern R to which the mask pattern H is transferred and the processed pattern T. Next, at the first auxiliary pattern arrangement unit 11b, the first auxiliary patterns are arranged at the corners of the mask pattern H to reduce rounding of the corners of the resist pattern R. Next, at the second auxiliary pattern arrangement unit 11c, the arrangement positions of the second auxiliary patterns are calculated according to the opening angle of the resist pattern R. Then, the second auxiliary patterns are arranged at the arrangement positions to reduce rounding of the corners of the resist pattern R. Then, correction data KM for the mask pattern H to be corrected at the mask pattern correction device 11 is transmitted to the mask data generation unit 13.

Then, at the mask data generation unit 13, mask data corresponding to designed layout patterns specified by the designed layout data N1 is generated, and the mask data is corrected based on the correction data KM. The correction data KM for the mask pattern H to be corrected at the mask pattern correction device 11 may be transmitted to the CAD system 12. Then, at the CAD system 12, the designed layout data N1 may be corrected based on the correction data KM. Then, on the photomask M, the mask pattern H corresponding to the corrected mask data generated at the mask data generation unit 13 is formed by a light-shielding film.

Meanwhile, as illustrated in FIG. 1B, a processed film TB is formed on a foundation layer K, and a resist film RB is applied to the processed film TB. The foundation layer K and the processed film TB may be semiconductor substrates, may be insulating films such as silicon dioxide films or silicon nitride films, may be semiconductor films of amorphous silicon, polycrystalline silicon or the like, or may be metallic films of Al, Cu or the like.

Then, exposure light such as ultraviolet light is emitted from the light source G, narrowed by the diaphragm S, and then entered into the resist film RB via the photomask M and the lens L to expose the resist film RB to the light.

Next, as illustrated in FIG. 1C, after exposure of the resist film RB, the resist film RB is developed to form the resist pattern R corresponding to the mask pattern H on the photomask M.

Next, as illustrated in FIG. 1D, the processed film TB is processed using as a mask the resist pattern R to which the mask pattern H is transferred, thereby to form the processed pattern T corresponding to the mask pattern H on the photomask M. The processing of the processed film TB may be etching or ion implantation.

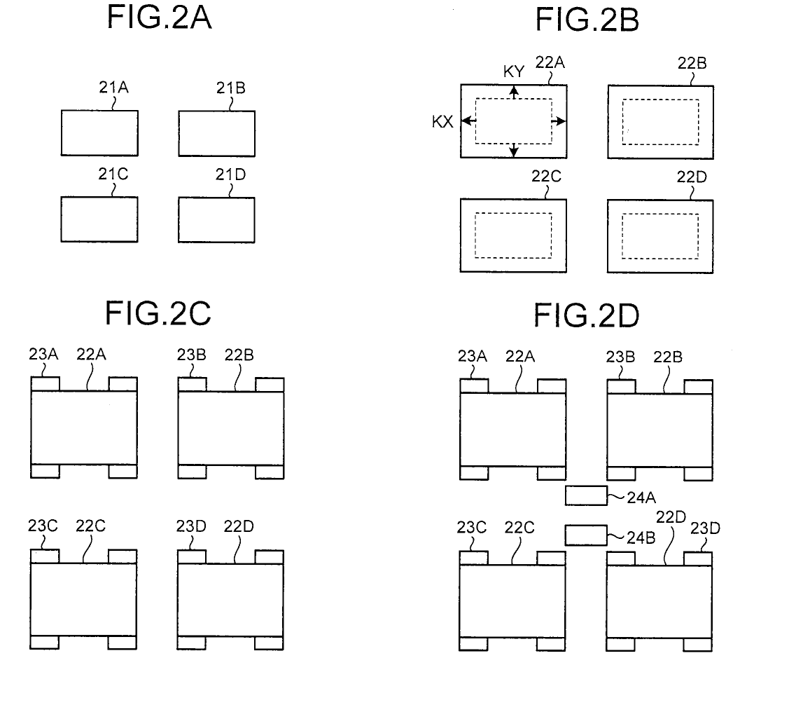

FIG. 2A is a plane view of one example of designed patterns for use in a mask pattern correction method according to the first embodiment, FIG. 2B is a plane view illustrating a method of compensating for process conversion differences in the designed patterns illustrated in FIG. 2A, FIG. 2C is a plane view of a configuration in which first auxiliary patterns are arranged on the designed patterns illustrated in FIG. 2B, and FIG. 2D is a plane view of a configuration in which second auxiliary patterns are arranged on the designed patterns illustrated in FIG. 2C.

Referring to FIG. 2A, designed layout patterns 21A to 21D are generated. The designed layout patterns 21A to 21D may be configured such that rectangular patterns are repeatedly aligned in the two-dimensional direction.

Next, as illustrated in FIG. 2B, the designed layout patterns 21A to 21D are offset by process conversion differences KX and KY to generate mask patterns 22A to 22D.

Next, as illustrated in FIG. 2C, first auxiliary patterns 23A to 23D are added to four corners of the mask patterns 22A to 22D, respectively. The first auxiliary patterns 23A to 23D can be set to a size with a resolution limit or less on light exposure. In addition, the first auxiliary patterns 23A to 23D are preferably enlarged in size to the maximum within a range of the resolution limit or less on light exposure.

Next, as illustrated in FIG. 2D, second auxiliary patterns 24A and 24B are arranged around the mask patterns 22A to 22D to which the first auxiliary patterns 23A to 23D are added. The second auxiliary patterns 24A and 24B can be arranged at a space between corners of the mask patterns 22A to 22D. The arrangement positions of the second auxiliary patterns 24A and 24B can be calculated based on an opening angle of the resist pattern R corresponding to the designed layout patterns 21A to 21D. In addition, the second auxiliary patterns 24A and 24B can be set to a size with a resolution limit or less on light exposure. In addition, the second auxiliary patterns 24A and 24B are preferably enlarged in size to the maximum within a range of the resolution limit or less on light exposure.

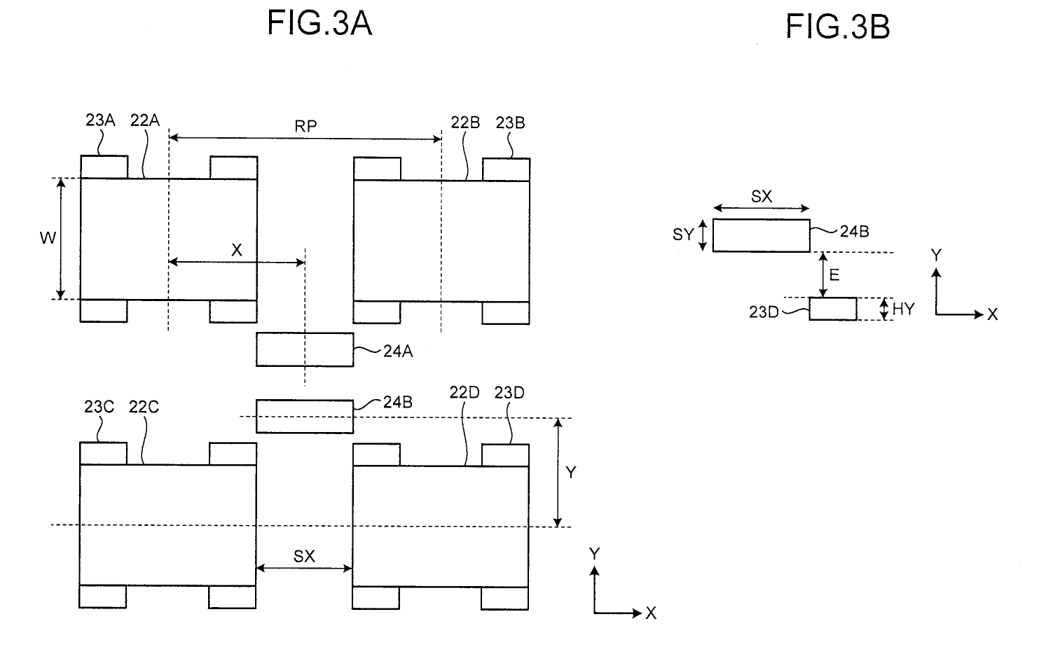

FIGS. 3A and 3B are plane views illustrating a method of arranging the first auxiliary patterns and the second auxiliary patterns.

Referring to FIG. 3A, the mask patterns 22A to 22D are repeatedly aligned in x direction and y direction. In the x direction, if the repeating pitch of the mask patterns 22A to 22D is designated as RP, distance X from the centers of the second auxiliary patterns 24A and 24B to the centers of the mask patterns 22A to 22D can be expressed by the following equation:

X=RP/2 (1)

In addition, in the y direction, if the width of the mask patterns 22A to 22D is designated as W, distance Y from the center of the mask pattern 22D to the center of the second auxiliary pattern 24B, for example, can be expressed by the following equation:

Y=W/2+(α+β×θ)+HY+E+SY/2 (2)

where α and β denotes coefficients determined by experiment, θ denotes an opening angle of resist patterns corresponding to the mask patterns 22B and 22D, HY denotes a dimension of the first auxiliary pattern 23D in the y direction, SY denotes a dimension of the second auxiliary pattern 24B in the y direction, E denotes a clearance between the first auxiliary pattern 23D adjacent to the second auxiliary pattern 24B and the second auxiliary pattern 24B in the y direction. The opening angle θ can be determined from height of and clearance between the resist patterns corresponding to the mask patterns 22B and 22D. The clearance E can be given by a minimum space value defined by each mask standard.

Dimension SX of the second auxiliary pattern 24B in the x direction can be given by a clearance SX between the mask patterns 22C and 22D in the x direction.

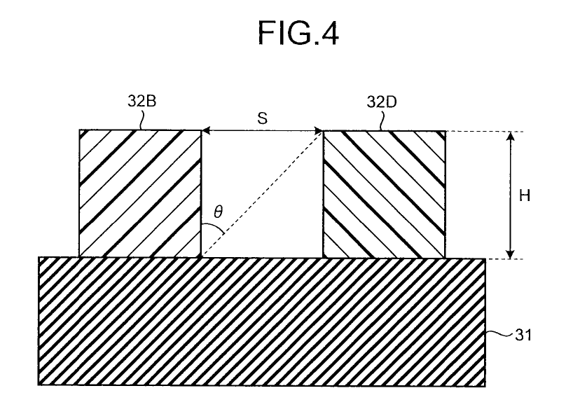

FIG. 4 is a cross-sectional view illustrating a method of calculating an opening angle in an opening angle model.

Referring to FIG. 4, the resist film is exposed via the mask patterns 22B and 22D and then is developed to form resist patterns 32B and 32D corresponding to the designed layout patterns 21B and 21D on a foundation layer 31. Here, the opening angle θ can be determined from height H of the resist patterns 32B and 32D and a clearance S between the resist patterns 32B and 32D. For example, if the resist patterns 32B and 32D have vertical cross sections, the opening angle θ can be given by tan θ=S/H.

In addition, referring to FIG. 2B, the process conversion differences KX and KY can be given based on the opening angle θ of the resist patterns corresponding to the designed layout patterns 21A to 21D. For example, the process conversion difference KY can be given by the term (β+β×θ) in equation (2).

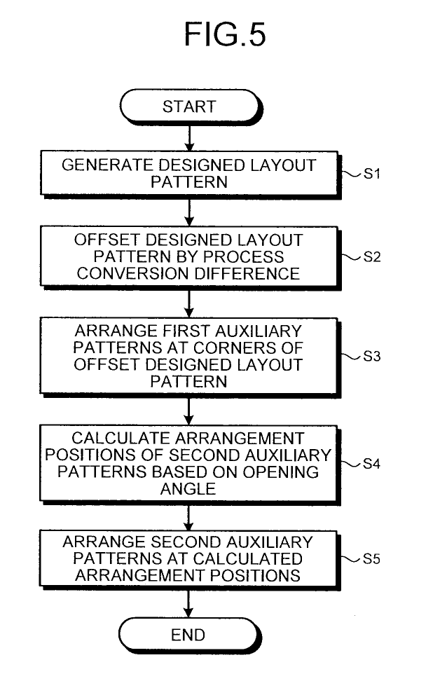

FIG. 5 is a flow chart of the mask pattern correction method according to the first embodiment.

Referring to FIG. 5, designed layout patterns in which rectangular patterns are repeatedly aligned in the two-dimensional direction are generated (S1). Next, the designed layout patterns are offset by process conversion differences (S2). Next, first auxiliary patterns are added to four corners of the designed layout patterns offset by the process conversion differences (S3). Next, the arrangement positions of second auxiliary patterns are calculated based on an opening angle of resist patterns corresponding to the designed layout patterns (S4). Next, the second auxiliary patterns 24A and 24B are arranged around the designed layout patterns to which the first auxiliary patterns are added (S5).

By providing the second auxiliary patterns to the designed layout patterns, it is possible to reduce rounding of corners of the resist patterns corresponding to the designed layout patterns and improve fidelity of the resist patterns to the designed layout patterns.

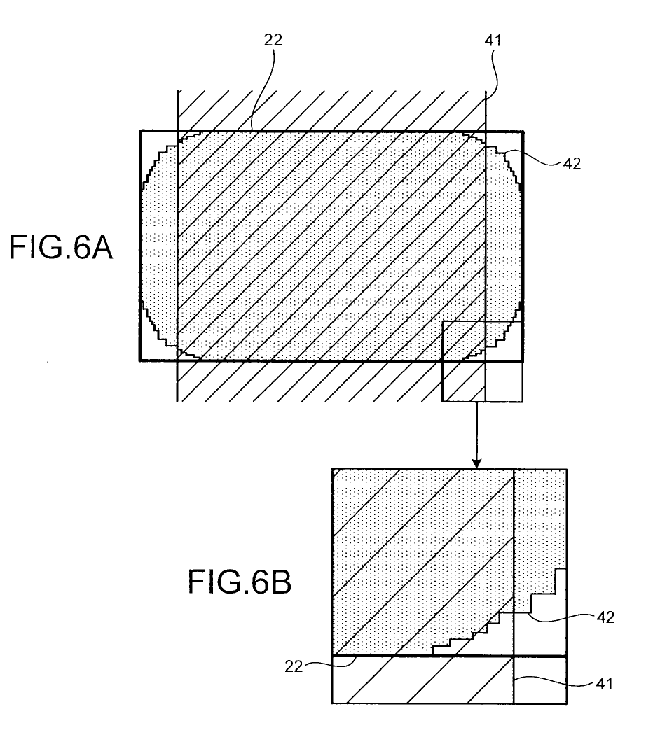

FIG. 6A is a plane view illustrating a result of simulation of a resist pattern without the first auxiliary patterns and the second auxiliary patterns, and FIG. 6B is an enlarged plane view of a corner of the resist pattern illustrated in FIG. 6A. In the simulation result, a resist pattern 42 for formation of a gate on an active region 41 is formed. In addition, a mask pattern 22 corresponding to the resist pattern 42 is overlaid.

Referring to FIG. 6A, in the case without first auxiliary patterns and second auxiliary patterns, rounding becomes large at four corners of the resist pattern 42. Accordingly, when a gate is formed on the active region 41 via the resist pattern 42, the gate length according to the designed value cannot be obtained at end portions of the active region 41.

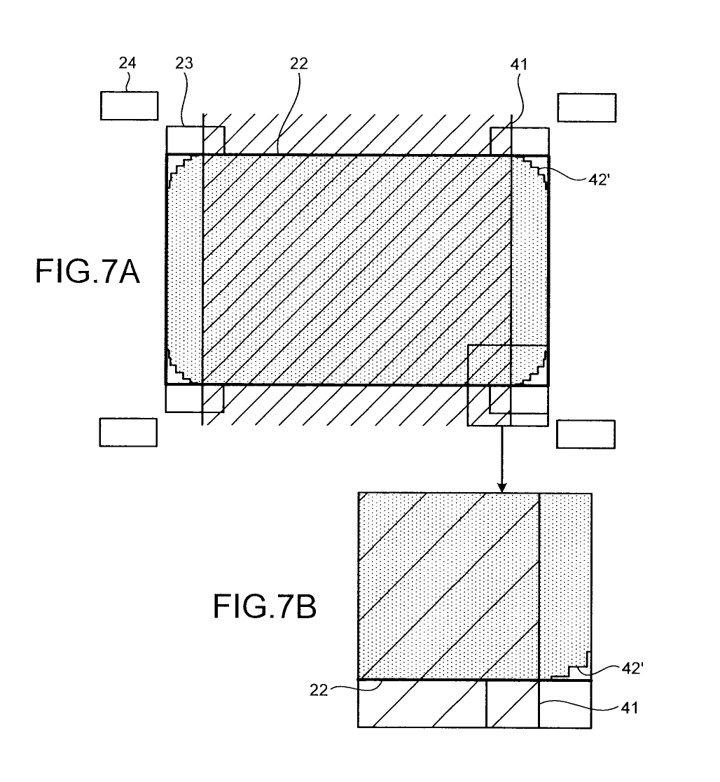

FIG. 7A is a plane view of a result of simulation of a resist pattern with the first auxiliary patterns and the second auxiliary patterns, and FIG. 7B is an enlarged plane view of a corner of the resist pattern illustrated in FIG. 7A.

Referring to FIG. 7A, in the case where there are first auxiliary patterns 23 and second auxiliary patterns 24, rounding is reduced at four corners of a resist pattern 42′. Accordingly, when a gate is formed on the active region 41 via the resist pattern 42′, the gate length according to the designed value can be obtained even at the end portions of the active region 41.

### Second Embodiment

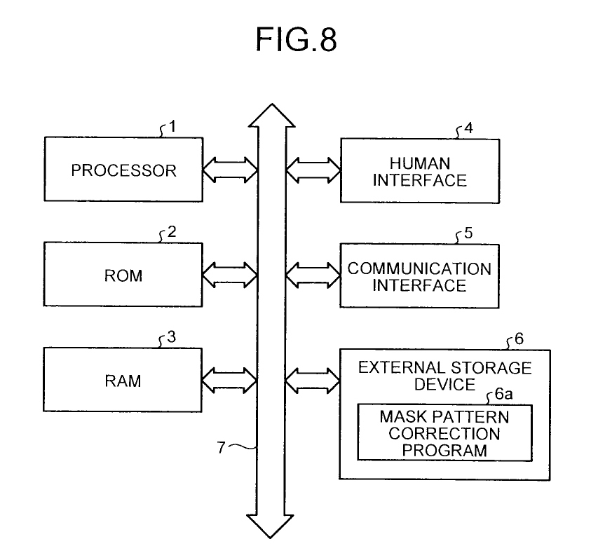

FIG. 8 is a block diagram of a hardware configuration of a pattern generation device according to a second embodiment.

Referring to FIG. 8, the mask pattern correction device 11 can be provided with a processor including a CPU or the like, a ROM 2 that stores fixed data, a RAM 3 that provides a work area to the processor 1, a human interface 4 that intermediates between a human and a computer, a communication interface 5 that provides a means for communications with the outside, and an external storage device 6 that stores programs for operating the processor 1 and various kinds of data. The processor 1, the ROM 2, the RAM 3, and the human interface 4, the communication interface 5, and the external storage device 6 are connected together via a bus 7.

The external storage device 6 can be a magnetic disc such as a hard disc, an optical disc such as a DVD, a portable semiconductor storage device such as a USB memory or a memory card, or the like, for example. The human interface 4 can be a keyboard, a mouse, or a touch panel as an input interface, and can be a display, a printer, or the like as an output interface. The communication interface 5 can be a LAN card, a modem, a router, or the like for connection with the Internet, a LAN, or the like. Here, the external storage device 6 has a mask pattern correction program 6a installed therein for correction of a mask pattern. The mask pattern correction program 6a can realize on a computer functions of the process conversion difference compensation unit 11a, the first auxiliary pattern arrangement unit 11b, and the second auxiliary pattern arrangement unit 11c illustrated in FIG. 1A.

In addition, when the mask pattern correction program 6a is executed on the processor 1, correction data for the designed layout data is calculated and transmitted to the CAD system 12 or the mask data generation unit 13.

The mask pattern correction program 6a to be executed on the processor 1 may be stored in advance in the external storage device 6 so as to be read by the RAM 3 on execution of the program, may be stored in advance in the ROM 2, or may be acquired via the communication interface 5. In addition, the mask pattern correction program 6a may be executed on a standalone computer or a cloud computer.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A mask pattern correction method, comprising:
arranging a first auxiliary pattern at a corner of a mask pattern;
calculating an arrangement position of a second auxiliary pattern based on an opening angle of a resist pattern to which the mask pattern is transferred; and
arranging the second auxiliary pattern at the arrangement position.

2. The mask pattern correction method according to claim 1, wherein the first auxiliary pattern and the second auxiliary pattern reduce rounding of the corner of the resist pattern.

3. The mask pattern correction method according to claim 1, wherein the resist pattern is corrected based on a process conversion difference between the resist pattern and the processed pattern.

4. The mask pattern correction method according to claim 3, wherein the process conversion difference is calculated based on the opening angle of the resist pattern.

5. The mask pattern correction method according to claim 1, wherein the mask pattern is a rectangular pattern repeatedly aligned at a predetermined pitch.

6. The mask pattern correction method according to claim 5, wherein
the first auxiliary pattern is arranged at four corners of the rectangular pattern; and
the second auxiliary pattern is arranged adjacent to the first auxiliary pattern.

7. The mask pattern correction method according to Claim 6, wherein the second auxiliary pattern is arranged so as to fill a space between the rectangular patterns.

8. A mask pattern correction method, comprising:
calculating a process conversion difference between a resist pattern and a processed pattern based on an opening angle of the resist pattern; and
correcting a mask pattern corresponding to the resist pattern based on the process conversion difference.

9. The mask pattern correction method according to claim 8, comprising:
arranging a first auxiliary pattern at a corner of the mask pattern;
calculating an arrangement position of a second auxiliary pattern based on the opening angle; and
arranging the second auxiliary pattern at the arrangement position.

10. The mask pattern correction method according to claim 9, wherein the first auxiliary pattern and the second auxiliary pattern reduce rounding of the corner of the resist pattern.

11. The mask pattern correction method according to claim 8, wherein the mask pattern is a rectangular pattern repeatedly aligned at a predetermined pitch.

12. The mask pattern correction method according to claim 11, wherein
the first auxiliary pattern is arranged at four corners of the rectangular pattern; and
the second auxiliary pattern is arranged adjacent to the first auxiliary pattern.

13. The mask pattern correction method according to claim 12, wherein the second auxiliary pattern is arranged so as to fill a space between the rectangular patterns.

14. A non-transitory computer-readable recording medium containing a mask pattern correction program for causing a computer to execute the step of:
arranging a first auxiliary pattern at a corner of a mask pattern;
calculating an arrangement position of a second auxiliary pattern based on an opening angle of a resist pattern to which the mask pattern is transferred; and
arranging the second auxiliary pattern at the arrangement position.

15. The non-transitory computer-readable recording medium according to claim 14, wherein the first auxiliary pattern and the second auxiliary pattern reduce rounding of the corner of the resist pattern.

16. The non-transitory computer-readable recording medium according to claim 14, wherein the resist pattern is corrected based on a process conversion difference between the resist pattern and the processed pattern.

17. The non-transitory computer-readable recording medium according to claim 16, wherein the process conversion difference is calculated based on the opening angle of the resist pattern.

18. The non-transitory computer-readable recording medium according to claim 14, wherein the mask pattern is a rectangular pattern repeatedly aligned at a predetermined pitch.

19. The non-transitory computer-readable recording medium according to claim 18, wherein
the first auxiliary pattern is arranged at four corners of the rectangular pattern; and
the second auxiliary pattern is arranged adjacent to the first auxiliary pattern.

20. The non-transitory computer-readable recording medium according to claim 19, wherein the second auxiliary pattern is arranged so as to fill a space between the rectangular patterns.
